(19) United States
(12) Patent Application Publication
(10) Pub. No.: US 2023/0129516 A1
(43) Pub. Date: Apr. 27, 2023

(54) PARTS MOUNTING SYSTEM AND PARTS MOUNTING METHOD

(71) Applicant: YAMAHA HATSUDOKI KABUSHIKI KAISHA, Iwata-shi, Shizuoka (JP)

(72) Inventors: Hiroaki NITTA, Iwata-shi (JP); Norimitsu SUZUKI, Iwata-shi (JP); Toshihiro MICHIZOE, Iwata-shi (JP)

(73) Assignee: YAMAHA HATSUDOKI KABUSHIKI KAISHA, Iwata-shi, Shizuoka (JP)

(21) Appl. No.: 17/905,377

(22) PCT Filed: Mar. 2, 2020
(86) PCT No.: PCT/JP2020/008638

§ 371 Date: Aug. 31, 2022

(51) Int. Cl. H05K 13/08

(52) U.S. Cl. CPC H05K 13/086

(57) ABSTRACT

A parts mounting system (100) includes a parts mounting device (15) configured to mount parts (E) on a board (S), a parts storage (20) configured to store the parts supplied to the parts mounting device, and a controller (30) configured or programmed to perform a control to detect whether or not an unloading order can be changed based on whether or not the parts can be supplied to the parts mounting device in time when an order in which the parts are unloaded from the parts storage is changed.

### CROSS-REFERENCE TO RELATED APPLICATION

This application is a National Stage of International Patent Application No. PCT/JP2020/008638, filed Mar. 2, 2020, the entire content of which is incorporated herein by reference.

### BACKGROUND

### Technical Field

The present disclosure relates to a parts mounting system and a parts mounting method, and more particularly, it relates to a parts mounting system including a parts storage and a parts mounting method using a parts storage.

### Background Art

Conventionally, a parts mounting system including a parts storage is known. Such a parts mounting system is disclosed in Japanese Patent Laid-Open No. 2019-091771, for example.

Japanese Patent Laid-Open No. 2019-091771 discloses a parts mounting system including a parts mounting device to mount parts on a board, an automated storage (parts storage) to store the parts to be supplied to the parts mounting device, and a management controller to create a plan to unload the parts from an automated storage. This parts mounting system is configured to unload the parts from the automated storage based on the plan created by the management controller. This parts mounting system is configured to change the order in which the parts are unloaded from the automated storage based on an urgent request signal generated by a worker using a terminal device to urgently request the parts and unload the parts from the automated storage according to the changed unloading order.

### SUMMARY

However, the parts mounting system described in Japanese Patent Laid-Open No. 2019-091771 is configured to change the order in which the parts are unloaded from the automated storage based on the urgent request signal generated by the worker using the terminal device to urgently request the parts and unload the parts from the automated storage according to the changed unloading order. In this case, the order in which the parts are unloaded from the automated storage is automatically changed based on the urgent request signal, and thus some parts may not be supplied to the parts mounting device in time depending on the changed unloading order. In this case, when the unloading order is changed, the parts cannot be smoothly supplied to the parts mounting device.

Accordingly, the present disclosure provides a parts mounting system and a parts mounting method each capable of smoothly supplying parts to a parts mounting device even when an unloading order is changed.

A parts mounting system according to a first aspect of the present disclosure includes a parts mounting device configured to mount parts on a board, a parts storage configured to store the parts supplied to the parts mounting device, and a controller configured or programmed to perform a control to detect whether or not an unloading order can be changed based on whether or not the parts can be supplied to the parts mounting device in time when an order in which the parts are unloaded from the parts storage is changed.

The parts mounting system according to the first aspect of the present disclosure includes the controller configured or programmed to perform a control to detect whether or not the unloading order can be changed based on whether or not the parts can be supplied to the parts mounting device in time when the order in which the parts are unloaded from the parts storage is changed. Accordingly, the unloading order is changed after whether or not the parts can be supplied to the parts mounting device in time is confirmed, and thus it is possible to significantly reduce or prevent a delay in the supply of the parts to the parts mounting device due to the change of the unloading order. Consequently, it is possible to provide the parts mounting system capable of smoothly supplying the parts to the parts mounting device even when the unloading order is changed.

In the aforementioned parts mounting system according to the first aspect, the controller is preferably configured or programmed to perform a control to query in advance a worker involved in changing the unloading order regarding whether or not to permit the unloading order to be changed. It is preferable to query the worker who understands the latest production status regarding the change of the unloading order. Therefore, with the structure as described above, the unloading order can be changed while the intention of the worker involved in changing the unloading order is reflected, and thus it is possible to significantly reduce or prevent a change of the unloading order that is inconvenient for the worker involved in changing the unloading order. Consequently, even when the unloading order is changed, the parts can be more smoothly supplied to the parts mounting device.

In this case, the controller is preferably configured or programmed to perform a control to notify the worker involved in changing the unloading order of a detection result of whether or not the unloading order can be changed when the worker involved in changing the unloading order is queried in advance regarding whether or not to permit the unloading order to be changed. Accordingly, the worker involved in changing the unloading order can determine whether or not to permit the unloading order based on the detection result of whether or not the unloading order can be changed.

In the aforementioned structure in which the worker is queried in advance regarding whether or not to permit the unloading order, the controller is preferably configured or programmed to perform a control to not change the order in which the parts are unloaded from the parts storage when the worker who has been queried regarding whether or not to permit the unloading order to be changed responds that the unloading order cannot be permitted to be changed, and to change the order in which the parts are unloaded from the parts storage when the worker who has been queried regarding whether or not to permit the unloading order to be changed responds that the unloading order can be permitted to be changed. Accordingly, the unloading order can be changed while the intention of the worker involved in changing the unloading order is more reliably reflected, and thus it is possible to more reliably significantly reduce or prevent a change of the unloading order that is inconvenient for the worker involved in changing the unloading order.

In this case, the controller is preferably configured or programmed to perform a control to change the order in which the parts are unloaded from the parts storage even when the worker who has been queried regarding whether or not to permit the unloading order to be changed does not respond within a predetermined period of time. Accordingly, when the worker who has been queried regarding whether or not to permit the unloading order to be changed does not respond, the unloading order can be changed, and thus it is possible to significantly reduce or prevent the possibility that it becomes impossible to change the unloading order due to no response from the worker who has been queried regarding whether or not to permit the unloading order to be changed.

In the structure in which the worker is queried in advance regarding whether or not to permit the unloading order, the controller is preferably configured or programmed to allow whether or not the worker involved in changing the unloading order is queried in advance regarding whether or not to permit the unloading order to be changed to be set therein. Accordingly, in the production status that requires a query regarding whether or not to permit the unloading order to be changed, the setting is selected to make a query such that it is possible to significantly reduce or prevent an inconvenient change of the unloading order. In the production status that does not require a query regarding whether or not to permit the unloading order to be changed, the setting is selected not to make a query such that it is possible to save the worker the trouble of responding to whether or not to permit the unloading order to be changed.

In the aforementioned structure in which the worker is queried in advance regarding whether or not to permit the unloading order, the controller is preferably configured or programmed to perform a control to query in advance the worker involved in changing the unloading order regarding whether or not to permit the unloading order to be changed in response to an unloading order change request from a worker. Accordingly, when the worker requests the change of the unloading order according to their own convenience, the unloading order can be changed while the intention of the worker involved in changing the unloading order is reflected. Consequently, it is possible to effectively significantly reduce or prevent a change of the unloading order that is inconvenient for the worker involved in changing the unloading order.

In this case, the controller is preferably configured or programmed to perform a control to change the order in which the parts are unloaded from the parts storage such that a turn is advanced or delayed in response to the unloading order change request from the worker. Accordingly, when the order in which the parts are unloaded from the parts storage is changed such that the turn is advanced, the parts that are urgently needed can be quickly unloaded from the parts storage, and thus the urgently needed parts can be quickly supplied to the parts mounting device. When the order in which the parts are unloaded from the parts storage is changed such that the turn is delayed, the turn of the parts that are not urgently needed is delayed according to the convenience of the worker, such as not being able to collect the parts, such that other parts can be unloaded from the parts storage.

The aforementioned structure in which a control is performed in response to the unloading order change request from the worker preferably further includes a mobile terminal that is carried by the worker to create the unloading order change request. Accordingly, the unloading order change request can be created with the mobile terminal, and thus the worker can make the unloading order change request regardless of the location.

In this case, the mobile terminal is preferably configured to display an unloading order list and an unloading priority. Accordingly, the worker can make the unloading order change request while referring to the unloading order list and the unloading priority, and thus it is possible to easily make an appropriate unloading order change request.

In the aforementioned structure further including the mobile terminal, the controller is preferably configured or programmed to perform a control to notify the mobile terminal carried by the worker involved in changing the unloading order of a query regarding whether or not to permit the unloading order to be changed. Accordingly, the worker can receive the notification of the query regarding whether or not to permit the unloading order to be changed through the mobile terminal regardless of the location, and thus the worker can quickly and reliably confirm the query regarding whether or not to permit the unloading order to be changed.

The aforementioned structure in which the worker is queried in advance regarding whether or not to permit the unloading order preferably further includes a plurality of mounting lines including the parts mounting device, and the controller is preferably configured or programmed to perform a control to query in advance the worker in charge of a mounting line involved in changing the unloading order other than a specific mounting line among the plurality of mounting lines regarding whether or not to permit the unloading order to be changed in response to the unloading order change request from a worker in charge of the specific mounting line. Accordingly, when the worker in charge of the specific mounting line requests the change of the unloading order according to the convenience of their mounting line, the unloading order can be changed while the intention of the worker in charge of another mounting line involved in changing the unloading order is reflected. Consequently, it is possible to more effectively significantly reduce or prevent a change of the unloading order that is inconvenient for the worker involved in changing the unloading order.

In the aforementioned structure in which the worker is queried in advance regarding whether or not to permit the unloading order, the controller is preferably configured or programmed to perform a control to detect whether or not the order in which the parts are unloaded from the parts storage is changed based on an unloading priority, and to query in advance the worker involved in changing the unloading order regarding whether or not to permit the unloading order to be changed when it is detected that the order in which the parts are unloaded from the parts storage is changed. Accordingly, when the controller automatically changes the unloading order based on the priority, the unloading order can be changed while the intention of the worker involved in changing the unloading order is reflected. Consequently, it is possible to effectively significantly reduce or prevent a change of the unloading order that is inconvenient for the worker involved in changing the unloading order.

In this case, the parts mounting system preferably further includes a plurality of mounting lines including the parts mounting device, and the controller is preferably configured or programmed to perform a control to query in advance the worker in charge of a mounting line involved in changing the unloading order among the plurality of mounting lines regarding whether or not to permit the unloading order to be changed when it is detected that the order in which the parts are unloaded from the parts storage is changed. Accordingly, when the controller automatically changes the unloading order based on the priority, the unloading order can be changed while the intention of the worker in charge of the mounting line involved in changing the unloading order is reflected. Consequently, it is possible to more effectively significantly reduce or prevent a change of the unloading order that is inconvenient for the worker involved in changing the unloading order.

Therefore, a parts mounting method according to a second aspect of the present disclosure includes mounting parts on a board by a parts mounting device, unloading the parts supplied to the parts mounting device from a parts storage, and performing a control to detect whether or not an unloading order can be changed based on whether or not the parts can be supplied to the parts mounting device in time when an order in which the parts are unloaded from the parts storage is changed.

The parts mounting method according to the second aspect of the present disclosure includes performing a control to detect whether or not the unloading order can be changed based on whether or not the parts can be supplied to the parts mounting device in time when the order in which the parts are unloaded from the parts storage is changed. Accordingly, the unloading order is changed after whether or not the parts can be supplied to the parts mounting device in time is confirmed, and thus it is possible to significantly reduce or prevent a delay in the supply of the parts to the parts mounting device due to the change of the unloading order. Consequently, it is possible to provide the parts mounting method capable of smoothly supplying the parts to the parts mounting device even when the unloading order is changed.

According to the present disclosure, as described above, it is possible to provide the parts mounting system and the parts mounting method each capable of smoothly supplying the parts to the parts mounting device even when the unloading order is changed.

### BRIEF DESCRIPTION OF THE DRAWINGS

FIG. 1 is a block diagram showing a parts mounting system according to an embodiment of the present disclosure;

FIG. 2 is a diagram showing the overall structure of a parts mounting device of the parts mounting system according to the embodiment of the present disclosure;

FIG. 3 is a diagram showing an example of an unloading instruction list of the parts mounting system according to the embodiment of the present disclosure;

FIG. 4 is a flowchart for illustrating a manual unloading order change process of the parts mounting system according to the embodiment of the present disclosure;

FIG. 5 is a schematic view for illustrating the manual unloading order change process of the parts mounting system according to the embodiment of the present disclosure;

FIG. 6 is a schematic view for illustrating a first example of instructions per unit of unloading of the manual unloading order change process of the parts mounting system according to the embodiment of the present disclosure;

FIG. 7 is a schematic view for illustrating a second example of instructions per unit of unloading of the manual unloading order change process of the parts mounting system according to the embodiment of the present disclosure;

FIG. 8 is a flowchart for illustrating an automatic unloading order change process of the parts mounting system according to the embodiment of the present disclosure; and

FIG. 9 is a schematic view for illustrating the automatic unloading order change process of the parts mounting system according to the embodiment of the present disclosure.

### DETAILED DESCRIPTION

An embodiment embodying the present disclosure is hereinafter described on the basis of the drawings.

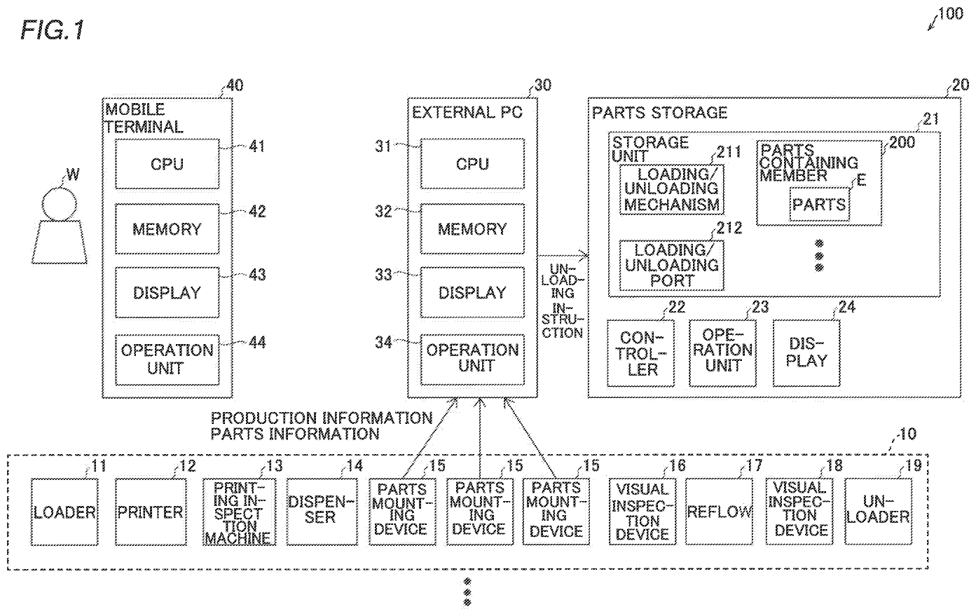

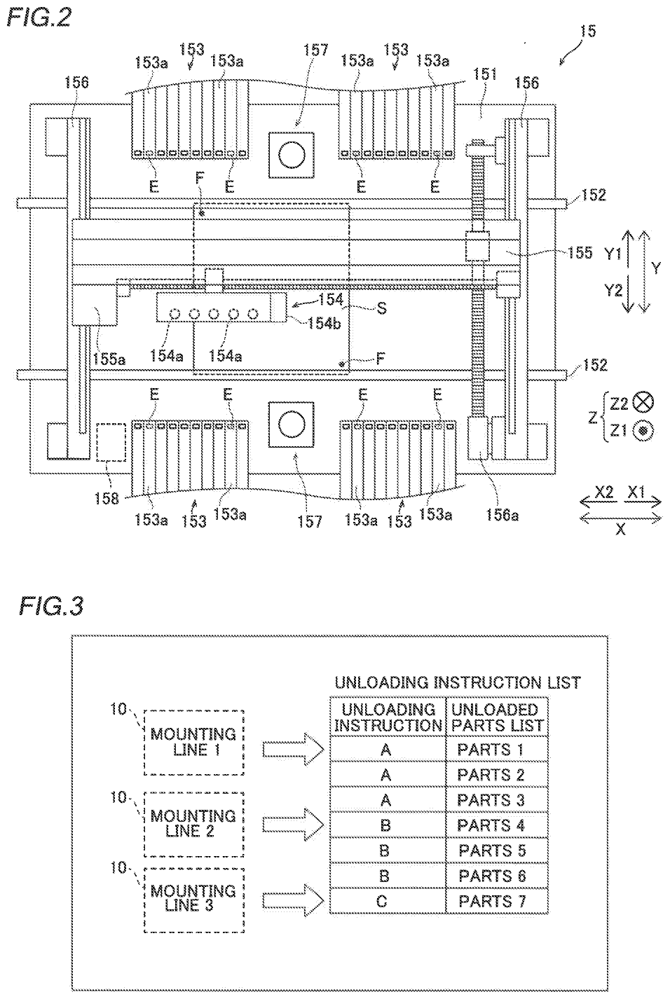

The structure of a parts mounting system 100 according to the embodiment of the present disclosure is now described with reference to FIGS. 1 and 2.

Structure of Parts Mounting System

The parts mounting system 100 according to this embodiment is configured to mount parts E on a board S to manufacture the board S on which the parts E have been mounted. As shown in FIG. 1, the parts mounting system 100 includes a mounting line 10, a parts storage 20, an external PC 30, and a mobile terminal 40 carried by a worker W who performs operations on the parts mounting system 100. The external PC 30 is an example of a “controller” in the claims.

A plurality of mounting lines 10 are provided. The mounting lines 10 each includes a loader 11, a printer 12, a printing inspection machine 13, a dispenser device 14, a plurality of parts mounting devices 15, a visual inspection device 16, a reflow device 17, and a visual inspection device 18, and unloader 19. In the mounting line 10, the board S is conveyed from the upstream side (left side) to the downstream side (right side) along the production line.

Structure of Mounting Line

The structure of each device of the mounting line 10 is now described.

The loader 11 has a role of holding the board (wiring board) S before the parts E are mounted and carrying the board S into the mounting line 10. The parts E include small pieces of electronic parts such as LSIs, ICs, transistors, capacitors, and resistors.

The printer 12 is a screen printer and has a function of applying cream solder on a mounting surface of the board S.

The printing inspection machine 13 has a function of inspecting the state of the cream solder printed by the printer 12.

The dispenser device 14 has a function of applying cream solder, an adhesive, etc. to the board S.

The parts mounting devices 15 have a function of mounting the parts at predetermined mounting positions on the board S on which cream solder has been printed. A plurality of (three) parts mounting devices 15 are arranged along the conveyance direction of the board S. The plurality of parts mounting devices 15 have the same or similar structure. As shown in FIG. 2, the parts mounting devices 15 each include a base 151, a pair of conveyors 152, parts supply units 153, a head unit 154, a support 155, a pair of rails 156, and parts recognition imagers 157, and a controller 158.

The pair of conveyors 152 are installed on the base 151 and convey the board S in an X direction. Furthermore, the pair of conveyors 152 hold the board S being conveyed in a stopped state at a mounting operation position. A distance between the pair of conveyors 152 in a Y direction can be adjusted according to the dimensions of the board S.

The parts supply units 153 are arranged outside (Y1 and Y2 sides) of the pair of conveyors 152. Furthermore, a plurality of tape feeders 153a are arranged in the parts supply units 153.

The tape feeders 153a hold reels (parts containing members 200 that contain a plurality of parts E (see FIG. 1)) on which tapes that hold the plurality of parts E at predetermined intervals are wound. The tape feeders 153a are configured to supply the parts E from the tip ends of the tape feeders 153a by rotating the reels to feed the tapes that hold the parts E. When the tape that holds the parts E is finished, it is replaced with the next tape (reel) (parts E). The tape (reel) (parts E) for replacement is unloaded from the parts storage 20 and replenished.

The head unit 154 is provided so as to move between an area above the pair of conveyors 152 and areas above the parts supply units 153. Furthermore, the head unit 154 includes a plurality of (five) mounting heads 154a having nozzles attached to the lower ends, and a board recognition imager 154b.

The mounting heads 154a are configured to mount the parts E on the board S. Specifically, the mounting heads 154a are configured to be movable up and down (movable in a Z direction), and are configured to suction and hold the parts E supplied from the tape feeders 153a by a negative pressure generated at the tip ends of the nozzles by an air pressure generator and to mount the parts E at the mounting positions on the board S.

The board recognition imager 154b is configured to image fiducial marks F of the board S in order to recognize the position and orientation of the board S. The positions of the fiducial marks F are imaged and recognized such that the mounting positions of the parts E on the board S can be accurately acquired. The board recognition imager 154b is configured to image the board S from above (Z1 direction side).

The support 155 includes an X-axis motor 155a. The support 155 is configured to move the head unit 154 in the X direction along the support 155 by driving the X-axis motor 155a. Opposite ends of the support 5 are supported by the pair of rails 156.

The pair of rails 156 are fixed on the base 151. A rail 156 on the X1 side includes a Y-axis motor 156a. The rails 156 are configured to move the support 155 in the Y direction orthogonal to the X direction along the pair of rails 156 by driving the Y-axis motor 156a. The head unit 154 is movable in the X direction along the support 155, and the support 155 is movable in the Y direction along the rails 156 such that the head unit 154 is movable in the X and Y directions.

The parts recognition imagers 157 are fixed on the upper surface of the base 151. The parts recognition imagers 157 are arranged outside (Y1 and Y2 sides) of the pair of conveyors 152. The parts recognition imagers 157 are configured to image the parts E suctioned by the nozzles of the mounting heads 154a from below (Z2 direction side) in order to recognize the suction states (suction orientations) of the parts E prior to mounting of the parts E. Thus, the suction states of the parts E suctioned by the nozzles of the mounting heads 154a can be acquired.

The controller 158 includes a central processing unit (CPU), and is configured to control the overall operation of the parts mounting device 15 such as the board S conveying operation performed by the pair of conveyors 152, the mounting operation performed by the head unit 154, and the imaging operations performed by the parts recognition imagers 157 and the board recognition imager 154b. Furthermore, the controller 158 is configured to transmit information such as production information and parts information to the external PC 30.

As shown in FIG. 1, the visual inspection device 16 is provided downstream of the plurality of parts mounting devices 15. The visual inspection device 16 has a function of inspecting the appearance of the board S on which the parts E have been mounted by the parts mounting devices 15.

The reflow device 17 has a function of melting the solder by performing a heat treatment and joining the parts E to electrode portions of the board S. The reflow device 17 is configured to perform a heat treatment while conveying the board S on the lane.

The visual inspection device 18 is provided downstream of the reflow device 17. The visual inspection device 18 has a function of inspecting the appearance of the board S heat-treated by the reflow device 17.

The unloader 19 has a role of discharging the board S on which the parts E have been mounted from the mounting line 10.

Structure of Parts Storage

The structure of the parts storage 20 is now described.

The parts storage 20 is configured to store the parts E to be supplied to the parts mounting devices 15. Specifically, the parts storage 20 is configured to store the parts containing members 200 containing the plurality of parts E. The parts storage 20 includes a storage unit 21, a controller 22, an operation unit 23, and a display 24. The storage unit 21 includes a loading/unloading mechanism 211 and a loading/unloading port 212.

The storage unit 21 is configured to store a plurality of parts E (a plurality of parts containing members 200). Information on each of the plurality of parts E stored in the storage unit 21 is stored and managed in a memory. The information on the parts E includes information on the type of parts E, information on the number of parts E, information on a storage location, and time information such as storage time. The loading/unloading mechanism 211 has a function of conveying the parts E. Specifically, the loading/unloading mechanism 211 conveys the parts E placed in the loading/unloading port 212 and loads the parts E to a predetermined storage position of the storage unit 21. Furthermore, the loading/unloading mechanism 211 conveys the parts E stored in the storage unit 21 and unloads the parts E to the loading/unloading port 212. A plurality of parts E can be arranged in the loading/unloading port 212. That is, the plurality of parts E can be loaded into and unloaded from the storage unit 21 at the same time.

For example, the loading/unloading port 212 includes a parts placement shelf (not shown) including a plurality of stages. The parts E (parts containing member 200), which are sequentially conveyed by the loading/unloading mechanism 211, are placed on each of the stages of the parts placement shelf. When unloading is completed, the worker (user) W can take out the parts E from each of the stages of the parts placement shelf. On the parts placement shelf, the parts E belonging to an unloading instruction list are arranged in order in succession in units of unloading described below. The worker takes out the parts E after the arrangement of all the parts E belonging to the unloading instruction list on the parts placement shelf is completed. The worker W can take out from each of the stages of the parts placement shelf the parts E that have been unloaded during unloading.

The controller 22 is configured to control each portion of the parts storage 20.

Specifically, the controller 22 performs a control to unload the parts E from the storage unit 21 in response to an unloading instruction from the external PC 30. As shown in FIG. 3, the controller 22 acquires the unloading instruction list created by the external PC 30. Furthermore, the controller 22 performs a control to sequentially unload the parts E based on the acquired unloading instruction list.

As shown in FIG. 1, the operation unit 23 receives an operation from the worker (user) W. The operation unit 23 includes an input such as a keyboard or a mouse, and a reader such as a barcode reader. The operation unit 23 receives a worker W's instruction based on a worker W's input through the keyboard or the mouse. Furthermore, the operation unit 23 reads an identifier (such as a bar code or an IC tag) attached to the parts containing member 200 by the reader, and receives information on the parts E to be loaded and unloaded.

The display 24 displays the state of the parts storage 20 and a screen for operation. Furthermore, the display 24 displays a notification issued from the parts storage 20.

Structure of External PC

The structure of the external PC (personal computer) 30 is now described.

The external PC 30 manages the mounting lines 10. Furthermore, the external PC 30 manages unloading of the parts E (parts containing members 200) based on the production information and the parts information transmitted from the parts mounting devices 15.

The external PC 30 includes a central processing unit (CPU) 31, a memory 32, a display 33, and an operation unit 34. The CPU 31 controls each portion of the external PC 30. The CPU 31 executes a predetermined program using the memory 32. The display 33 displays a screen for operating the external PC 30. The operation unit 34 receives an operation from the worker W (user). The operation unit 34 includes an input such as a keyboard or a mouse.

The external PC 30 is configured to determine the parts E (parts containing members 200) to be unloaded based on information on the number of remaining parts transmitted from the parts mounting device 15 at the predetermined timing. The external PC 30 calculates the parts shortage time (producible time) based on the production information (the cycle time of one board and the number of parts used for one board) and the parts information (the number of remaining parts) transmitted from each of the plurality of parts mounting devices 15 at regular time intervals. The external PC 30 extracts unloading instruction parts subject to the unloading instruction to the parts storage 20 based on the calculated parts shortage time. The external PC 30 creates the unloading instruction list based on the extracted unloading instruction parts, as shown in FIG. 3.

In an example shown in FIG. 3, the unloading instruction list including an unloading instruction A with three types of parts E, Parts 1 to 3 corresponding to the first mounting line 10, as a unit of unloading, an unloading instruction B with three types of parts E, Parts 4 to 6 corresponding to the second mounting line 10, as a unit of unloading, and an unloading instruction C with one type of parts E, Parts 7 corresponding to the third mounting line 10, as a unit of unloading is created. In this case, in the parts storage 20, three types of parts E, Parts 1 to 3, are unloaded as a unit of unloading, three types of parts E, Parts 4 to 6, are unloaded as a unit of unloading, and one type of parts E, Parts 7, is unloaded as a unit of unloading.

In this embodiment, the external PC 30 performs a control to detect whether or not the unloading order can be changed based on whether or not the parts E can be supplied to the parts mounting device 15 in time when changing the order in which the parts E are unloaded from the parts storage 20. When it is detected that the unloading order can be changed, the external PC 30 performs a control to query in advance the worker W involved in changing the unloading order regarding whether or not to permit the unloading order to be changed. Specifically, the external PC 30 performs a control to not change the order in which the parts E are unloaded from the parts storage 20 when the worker W who has been queried regarding whether or not to permit the unloading order to be changed responds that the unloading order cannot be permitted to be changed, and to change the order in which the parts E are unloaded from the parts storage 20 when the worker W who has been queried regarding whether or not to permit the unloading order to be changed responds that the unloading order can be permitted to be changed. Furthermore, the external PC 30 performs a control to change the order in which the parts E are unloaded from the parts storage 20 also when the worker W who has been queried regarding whether or not to permit the unloading order to be changed does not respond within a predetermined period of time. The control to change the unloading order is described below in detail.

Structure of Mobile Terminal

The structure of the mobile terminal 40 is now described.

As shown in FIG. 1, the mobile terminal 40 is carried by the worker (user) W who manages the parts mounting system 100. The mobile terminal 40 receives information on the parts mounting system 100 and displays it on a display 43. Furthermore, using the mobile terminal 40, an unloading order change request requesting a change of the order in which the parts E are unloaded from the parts storage 20 can be created.

The mobile terminal 40 includes a central processing unit (CPU) 41, a memory 42, the display 43, and an operation unit 44. The CPU 41 controls each portion of the mobile terminal 40. Furthermore, the CPU 41 executes a predetermined program using the memory 42. The display 43 displays a screen for operating the mobile terminal 40. The operation unit 44 receives an operation from the user. The operation unit 44 includes an input such as a touch panel. The worker W can create the unloading order change request by operating the operation unit 44.

Manual Unloading Order Change Process

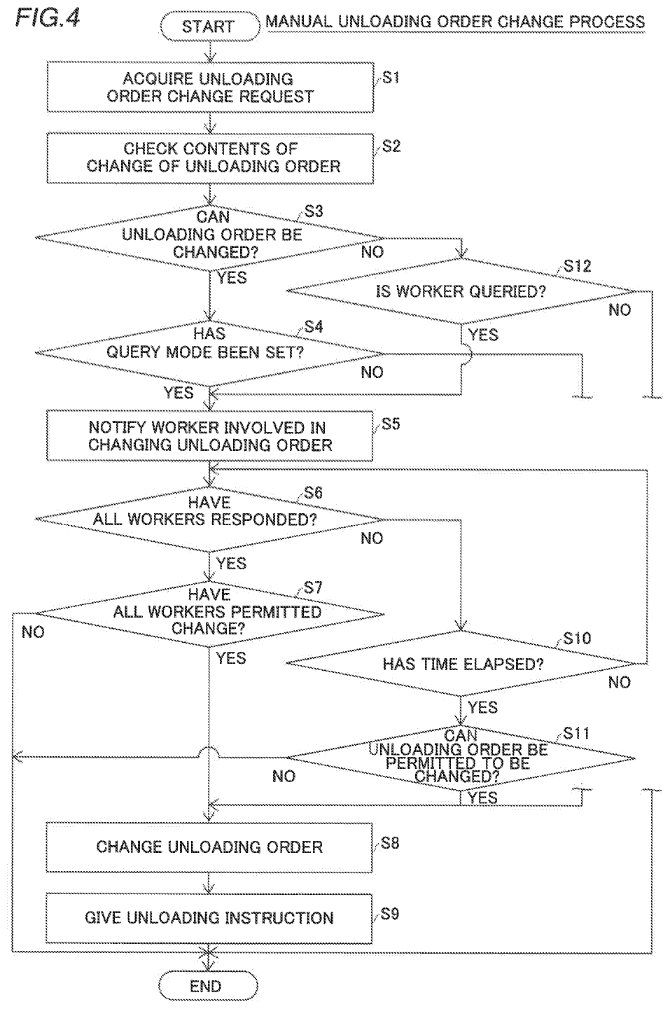

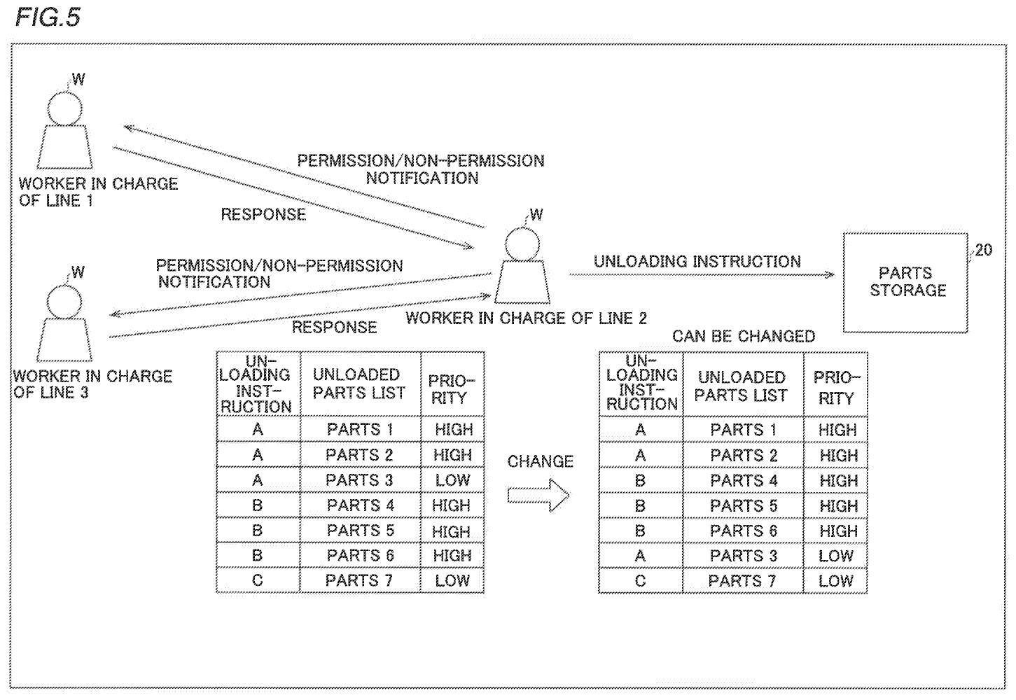

A manual unloading order change process is now described with reference to FIGS. 4 to 7. The manual unloading order change process is performed by the external PC 30.

As shown in FIG. 4, in step S1, the external PC 30 acquires the unloading order change request transmitted from the mobile terminal 40 carried by the worker W.

As shown in FIG. 5, the worker W creates the unloading order change request using the mobile terminal 40 and transmits it to the external PC 30. At this time, the mobile terminal 40 can display an unloading order list (unloading instruction list) and an unloading priority. The worker W can create the unloading order change request while referring to the unloading order list and the unloading priority displayed on the mobile terminal 40. The unloading order list is a list showing the current unloading order of the parts E. The unloading priority is a parameter indicating the urgency of unloading of the parts E, which is determined based on the parts shortage time. As the parts shortage time increases, the unloading priority decreases, and as the parts shortage time decreases, the unloading priority increases.

In an example shown in FIG. 5, the worker W in charge of the second mounting line 10 creates the unloading order change request using the mobile terminal 40. Specifically, in the example shown in FIG. 5, the unloading order change request is created to change the order in which the parts E are unloaded from the parts storage 20 such that turns of three types of parts E, Parts 4 to 6, are advanced. More specifically, in the example shown in FIG. 5, the unloading order change request is created to change the order in which the parts E are unloaded from the parts storage 20 such that three types of parts E, Parts 4 to 6, cut in between the parts E of Parts 2 and the parts E of Parts 3.

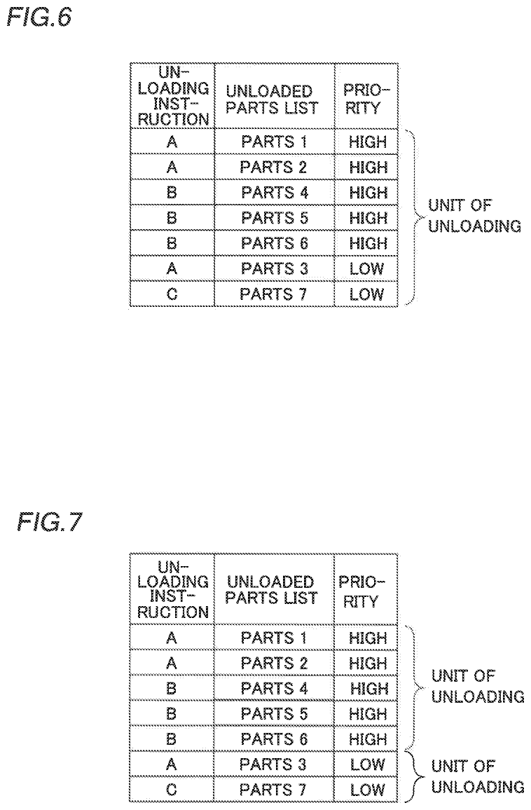

As shown in FIGS. 6 and 7, the worker W can set a unit of unloading using the mobile terminal 40 when creating the unloading order change request. In an example shown in FIG. 6, a unit of unloading including all the parts E of Parts 1 to 7 is set. In an example shown in FIG. 7, a plurality of units of unloading including a unit of unloading including five types of parts E, Parts 1, 2, and 4 to 6, and a unit of unloading including two types of parts E, Parts 3 and 7, are set.

As shown in FIG. 4, in step S2, the external PC 30 performs a control to check the contents of the change of the unloading order requested by the unloading order change request. Specifically, the external PC 30 performs a control to detect whether or not the requested change of the unloading order is possible based on the contents of the change of the unloading order. That is, the external PC 30 performs a control to detect whether or not the requested change of the unloading order is possible based on whether or not the parts E can be supplied to the parts mounting device 15 in time in the changed unloading order. The external PC 30 performs a control to detect that the requested change of the unloading order is not possible when there are the parts E that cannot be supplied to the parts mounting device 15 in time in the changed unloading order. The external PC 30 performs a control to detect that the requested change of the unloading order is possible when there are not the parts E that cannot be supplied to the parts mounting device 15 in time in the changed unloading order. Detecting whether or not the parts E can be supplied to the parts mounting device 15 in time in the changed unloading order is described below in detail.

Then, in step S3, the external PC 30 determines whether or not the unloading order can be changed. When determining in step S3 that the unloading order can be changed, the external PC 30 advances to step S4.

Then, in step S4, the external PC 30 determines whether or not a mode (query mode) has been set in which the worker W involved in changing the unloading order is queried in advance regarding whether or not to permit the unloading order to be changed. In the external PC 30, whether or not the worker W involved in changing the unloading order is queried in advance regarding whether or not to permit the unloading order to be changed is settable. The worker W can set in advance whether to enable or disable the query mode using the operation unit 34 of the external PC 30, for example.

When determining in step S4 that the query mode has not been set, the external PC 30 advances to step S8. When determining in step S4 that the query mode has been set, the external PC 30 advances to step S5.

Then, in step S5, the external PC 30 performs a control to query in advance the worker W involved in changing the unloading order regarding whether or not to permit the unloading order to be changed in response to the unloading order change request from the worker W. Specifically, the external PC 30 performs a control to notify the mobile terminal 40 carried by the worker W involved in changing the unloading order of a query regarding whether or not to permit the unloading order to be changed.

In the example shown in FIG. 5, in response to the unloading order change request from the worker W in charge of the second mounting line 10, the mobile terminal 40 of the worker W involved in changing the unloading order in charge of the first mounting line 10, and the mobile terminal 40 of the worker W involved in changing the unloading order in charge of the third mounting line 10 are notified of a query regarding whether or not to permit the unloading order to be changed. The worker W in charge of the first mounting line 10 and the worker W in charge of the third mounting line 10 can respond to the query regarding whether or not to permit the unloading order to be changed using the mobile terminals 40.

Thus, the external PC 30 performs a control to query in advance the worker W in charge of the mounting line 10 involved in changing the unloading order other than the specific mounting line 10 regarding whether or not to permit the unloading order to be changed in response to the unloading order change request from the worker W in charge of the specific mounting line 10.

As shown in FIG. 4, in step S6, the external PC 30 performs a control to detect whether or not all of the workers W who have been queried regarding whether or not to permit the unloading order to be changed have responded. When it is detected in step S6 that all the workers W have responded, the external PC 30 advances to step S7.

Then, in step S7, the external PC 30 performs a control to detect whether or not all the workers W have responded that the unloading order can be permitted to be changed. When it is detected in step S7 that some workers W (at least one worker W) have responded that the unloading order cannot be permitted to be changed, the unloading order cannot be changed, and thus the manual unloading order change process is terminated. When it is detected in step S7 that all the workers W have responded that the unloading order can be permitted to be changed, the external PC 30 advances to step S8.

Then, in step S8, the external PC 30 performs a control to change the order in which the parts E are unloaded from the parts storage 20 such that the turn is advanced or delayed in response to the unloading order change request from the worker W. Although FIG. 5 shows an example in which the order in which the parts E are unloaded from the parts storage 20 is changed such that the turns are advanced, the present disclosure is not limited to this example. The order in which the parts E are unloaded from the parts storage 20 can be changed such that the turns are delayed.

Then, in step S9, the external PC 30 gives an unloading instruction to the parts storage 20 according to the unloading order changed in response to the unloading order change request from the worker W. After that, the manual unloading order change process is terminated.

when it is detected in step S6 that at least one worker W has not responded, the external PC 30 advances to step S10.

Then, in step S10, the external PC 30 performs a control to detect whether or not a predetermined period of time has elapsed from the time at which the mobile terminal 40 is notified of the query regarding whether or not to permit the unloading order to be changed. When it is detected in step S10 that the predetermined period of time has not elapsed, the external PC 30 advances to step S6, and the process operation in step S6 is repeated. When it is detected in step S10 that the predetermined period of time has elapsed, the external PC 30 advances to step S11.

Then, in step S11, the external PC 30 performs a control to detect whether or not there is at least one worker W who has responded that the unloading order cannot be permitted to be changed among the workers W who have responded. When it is detected in step S11 that there is at least one worker W who has responded that the unloading order cannot be permitted to be changed among the workers W who have responded, the unloading order cannot be changed, and thus the manual unloading order change process is terminated. When it is detected in step S11 that there is no worker W who has responded that the unloading order cannot be permitted to be changed among the workers W who have responded, the external PC 30 advances to step S8. After that, the process operations in step S8 and step S9 are performed, and the manual unloading order change process is terminated. When the process operations in step S8 and step S9 are performed via step S11, the worker W who has not responded within the predetermined period of time may be notified that the unloading order has been changed.

When it is determined in step S3 that the unloading order cannot be changed, the worker W (mobile terminal 40) who has created the unloading order change request is notified that the unloading order cannot be changed. Thus, the worker W can visually confirm that the unloading order cannot be changed using the mobile terminal 40.

Even when it is determined in step S3 that the unloading order cannot be changed, the unloading order may be changed depending on the latest production status. Therefore, using the mobile terminal 40, the worker W who has confirmed that the unloading order cannot be changed selects whether or not to query the worker W involved in changing the unloading order regarding whether or not to permit the unloading order to be changed.

Then, in step S12, the external PC 30 determines whether or not to query the worker W involved in changing the unloading order regarding whether or not to permit the unloading order to be changed according to the selection of the worker W. When determining in step S12 that the worker W is queried regarding whether or not to permit the unloading order to be changed, the external PC 30 advances to step S5. Then, in step S5, the external PC 30 performs a control to query in advance the worker W involved in changing the unloading order regarding whether or not to permit the unloading order to be changed. At this time, the external PC 30 performs a control to notify the worker W involved in changing the unloading order of the detection result of whether or not the unloading order can be changed together with the query. That is, the external PC 30 performs a control to notify the worker W involved in changing the unloading order that the detection result that the unloading order cannot be changed according to the calculation of the external PC 30 has been acquired. Not only when it is determined in step S3 that the unloading order cannot be changed, but also when it is determined in step S3 that the unloading order can be changed, the worker W involved in changing the unloading order may be notified of the detection result of whether or not the unloading order can be changed.

After that, the process operations in step S6 to step S11 are appropriately performed. When the external PC 30 advances to step S10 via step S12 and detects in step S10 that the predetermined period of time has elapsed, the manual unloading order process may be terminated without advancing to step S11.

When it is determined in step S12 that the worker W is not queried regarding whether or not to permit the unloading order to be changed, the unloading order is not changed, and thus the manual unloading order process is terminated.

Automatic Unloading Order Change Process

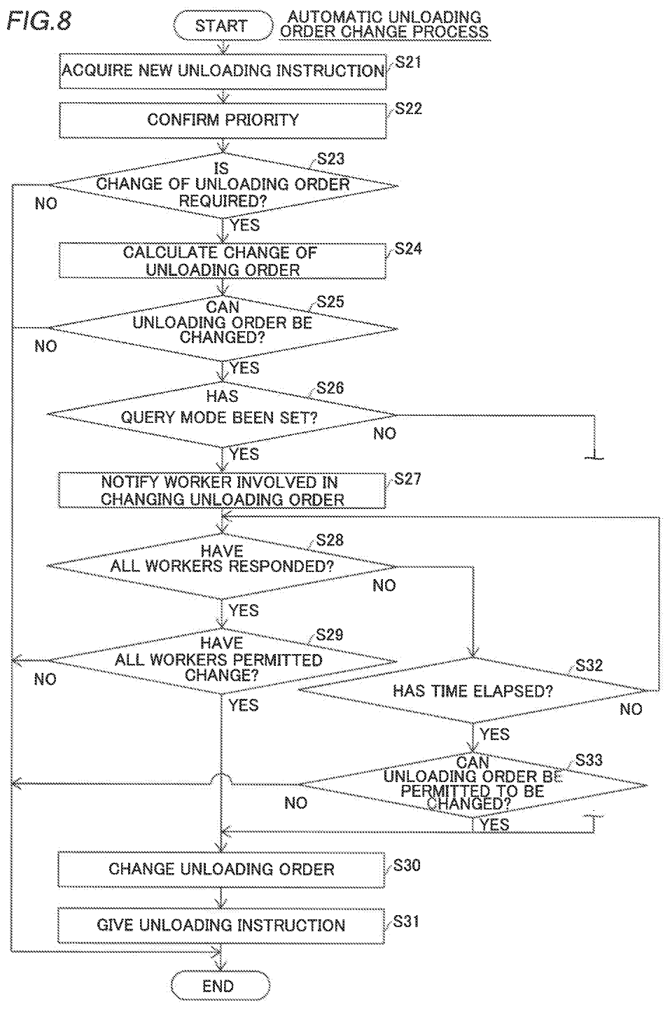

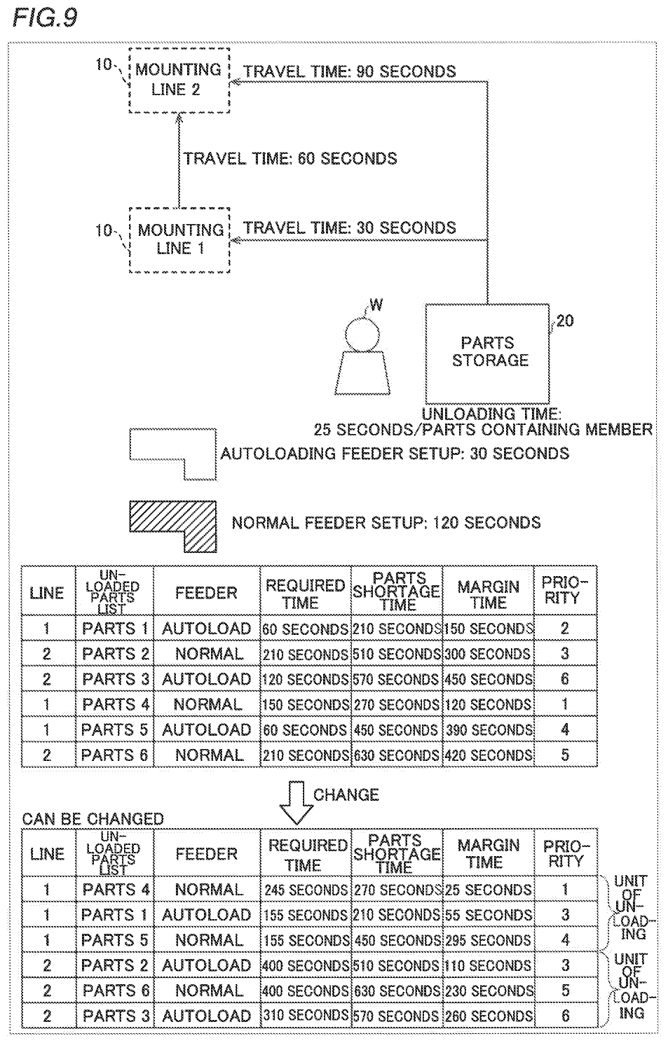

An automatic unloading order change process is now described with reference to FIGS. 8 and 9. The automatic unloading order change process is performed by the external PC 30.

As shown in FIG. 8, in step S21, the external PC 30 acquires a new unloading instruction. Specifically, the external PC 30 extracts the unloading instruction parts subject to the unloading instruction to the parts storage 20 and acquires a new unloading instruction based on the production information (the cycle time of one board and the number of parts used for one board) and the parts information (the number of remaining parts) transmitted from each of the plurality of parts mounting devices 15.

Then, in step S22, the external PC 30 confirms the unloading priority of the new unloading instruction.

Then, in step S23, the external PC 30 performs a control to detect whether or not the order in which the parts E are unloaded from the parts storage 20 is changed based on the unloading priority. When it is detected in step S23 that the order in which the parts E are unloaded from the parts storage 20 is not changed, the automatic unloading order change process is terminated. When it is detected in step S23 that the order in which the parts E are unloaded from the parts storage 20 is changed, the external PC 30 advances to step S24.

Then, in step S24, the external PC 30 calculates a change of the unloading order based on the unloading priority.

Specifically, as shown in FIG. 9, the external PC 30 calculates the change of the unloading order based on the unloading priority based on the margin time determined based on the parts shortage time and the required time. The required time includes the travel time from the parts storage 20 to the supply destination (mounting line 10) of the parts E and the mounting time of the parts E. In an example shown in FIG. 9, the travel time from the parts storage 20 to the first mounting line 10 is 30 seconds, and the travel time from the parts storage 20 to the second mounting line 10 is 90 seconds. In the example shown in FIG. 9, the mounting time of the parts E with respect to an auto-loading feeder is 30 seconds, and the mounting time of the parts E with respect to a normal feeder is 120 seconds. The margin time is a time that takes into account the parts shortage time and the required time. In the example shown in FIG. 9, the margin time is the time obtained by subtracting the required time from the parts shortage time. As the margin time decreases, the unloading priority increases, and as the margin time increases, the unloading priority decreases.

The external PC 30 calculates the change of the unloading order such that the turn of the parts E having a higher unloading priority is advanced. At this time, the external PC 30 calculates the change of the unloading order such that a unit of unloading is set for each mounting line 10. In the example shown in FIG. 9, a plurality of units of unloading including a unit of unloading including three types of parts E, Parts 4, 1, and 5 corresponding to the first mounting line 10, and a unit of unloading including three types of parts E, Parts 2, 6, and 3 corresponding to the second mounting line 10, are set.

In step S24, the external PC 30 performs a control to check the contents of the change of the unloading order. Specifically, the external PC 30 performs a control to detect whether or not the unloading order can be changed based on the contents of the change of the unloading order. That is, the external PC 30 performs a control to detect whether or not the unloading order can be changed based on whether or not the parts E can be supplied to the parts mounting device 15 in time in the changed unloading order. The external PC 30 performs a control to detect that the unloading order cannot be changed when there are the parts E that cannot be supplied to the parts mounting device 15 in time in the changed unloading order. The external PC 30 performs a control to detect that the unloading order can be changed when there are not the parts E that cannot be supplied to the parts mounting device 15 in time in the changed unloading order.

FIG. 9 shows an example in which there are not the parts E that cannot be supplied to the parts mounting device 15 in time in the changed unloading order. Specifically, FIG. 9 shows an example in which the margin time is not reduced to less than 0 seconds in the changed unloading order. In the changed unloading order, the required time includes the unloading time of the parts E (parts containing member 200) from the parts storage 20 and the collection time of the unloaded parts E in addition to the travel time and the mounting time of the parts E.

In the example shown in FIG. 9, the unloading time of the parts E from the parts storage 20 is 25 seconds per parts containing member 200. The collection time of the unloaded parts E is 20 seconds. Therefore, in addition to the required time before the change of the unloading order, 95 seconds (25 seconds×3+20 seconds) are added to the required time of the parts E of Parts 4, 1, and 5. In addition to the required time before the change of the unloading order, 190 seconds (25 seconds×3+20 seconds+25 seconds×3+20 seconds) are added to the required time of the parts E of Parts 2, 6, and 3. When the margin time is less than 0 seconds in the changed unloading order, the parts E may not be supplied to the parts mounting device 15 in time. A threshold (>0) other than 0 seconds may be set to determine whether the parts E cannot be supplied to the parts mounting device 15 in time.

As shown in FIG. 8, in step S25, the external PC 30 determines whether or not the unloading order can be changed. When it is determined in step S25 that the unloading order cannot be changed, the unloading order cannot be changed, and thus the automatic unloading order change process is terminated. When it is determined in step S25 that the unloading order can be changed, the external PC 30 advances to step S26.

Then, in step S26, the external PC 30 determines whether or not the query mode has been set in which the worker W involved in changing the unloading order is queried in advance regarding whether or not to permit the unloading order to be changed.

When determining in step S26 that the query mode has not been set, the external PC 30 advances to step S30. When determining in step S26 that the query mode has been set, the external PC 30 advances to step S27.

Then, in step S27, the external PC 30 performs a control to query in advance the worker W involved in changing the unloading order regarding whether or not to permit the unloading order to be changed. Specifically, the external PC 30 performs a control to notify the mobile terminal 40 carried by the worker W involved in changing the unloading order of a query regarding whether or not to permit the unloading order to be changed.

In the example shown in FIG. 9, the mobile terminal 40 of the worker W involved in changing the unloading order in charge of the first mounting line 10 and the mobile terminal 40 of the worker W involved in changing the unloading order in charge of the second mounting line 10 are notified of a query regarding whether or not to permit the unloading order to be changed according to the automatic change of the unloading order based on the unloading priority. The worker W in charge of the first mounting line 10 and the worker W in charge of the second mounting line 10 can respond to the query regarding whether or not to permit the unloading order to be changed using the mobile terminals 40.

Thus, when it is detected that the order in which the parts E are unloaded from the parts storage 20 is changed based on the unloading priority, the external PC 30 performs a control to query in advance the worker W in charge of the mounting lines 10 involved in changing the unloading order among the plurality of mounting lines 10 regarding whether or not to permit the unloading order to be changed.

As shown in FIG. 8, in step S28, the external PC 30 performs a control to detect whether or not all of the workers W who have been queried regarding whether or not to permit the unloading order to be changed have responded. When it is detected in step S28 that all the workers W have responded, the external PC 30 advances to step S29.

Then, in step S29, the external PC 30 performs a control to detect whether or not all the workers W have responded that the unloading order can be permitted to be changed. When it is detected in step S29 that some workers W (at least one worker W) have responded that the unloading order cannot be permitted to be changed, the unloading order cannot be changed, and thus the automatic unloading order change process is terminated. When it is detected in step S29 that all the workers W have responded that the unloading order can be permitted to be changed, the external PC 30 advances to step S30.

Then, in step S30, the external PC 30 performs a control to change the order in which the parts E are unloaded from the parts storage 20 as calculated in the step S24.

Then, in step S31, the external PC 30 gives an unloading instruction to the parts storage 20 according to the unloading order changed based on the unloading priority. After that, the automatic unloading order change process is terminated.

When it is detected in step S28 that at least one worker W has not responded, the external PC 30 advances to step S32.

Then, in step S32, the external PC 30 performs a control to detect whether or not a predetermined period of time has elapsed from the time at which the mobile terminal 40 is notified of the query regarding whether or not to permit the unloading order to be changed.

When it is detected in step S32 that the predetermined period of time has not elapsed, the external PC 30 advances to step S28, and the process operation in step S28 is repeated. When it is detected in step S32 that the predetermined period of time has elapsed, the external PC 30 advances to step S33.

Then, in step S33, the external PC 30 performs a control to detect whether or not there is at least one worker W who has responded that the unloading order cannot be permitted to be changed among the workers W who have responded. When it is detected in step S33 that there is at least one worker W who has responded that the unloading order cannot be permitted to be changed among the workers W who have responded, the unloading order cannot be changed, and thus the automatic unloading order change process is terminated. When it is detected in step S33 that there is no worker W who has responded that the unloading order cannot be permitted to be changed among the workers W who have responded, the external PC 30 advances to step S30. After that, the process operations in step S30 and step S31 are performed, and the automatic unloading order change process is terminated. When the process operations in step S30 and step S31 are performed via step S33, the worker W who has not responded within the predetermined period of time may be notified that the unloading order has been changed.

According to this embodiment, the following advantageous effects are achieved.

According to this embodiment, as described above, the parts mounting system 100 includes the external PC 30 configured or programmed to perform a control to detect whether or not the unloading order can be changed based on whether or not the parts E can be supplied to the parts mounting device 15 in time when the order in which the parts E are unloaded from the parts storage 20 is changed. Accordingly, the unloading order is changed after whether or not the parts can be supplied to the parts mounting device 15 in time is confirmed, and thus it is possible to significantly reduce or prevent a delay in the supply of the parts E to the parts mounting device 15 due to the change of the unloading order. Consequently, even when the unloading order is changed, the parts can be smoothly supplied to the parts mounting device 15.

According to this embodiment, as described above, the external PC 30 is configured or programmed to perform a control to query in advance the worker W involved in changing the unloading order regarding whether or not to permit the unloading order to be changed. It is preferable to query the worker W who understands the latest production status regarding the change of the unloading order. Therefore, with the structure as described above, the unloading order can be changed while the intention of the worker W involved in changing the unloading order is reflected, and thus it is possible to significantly reduce or prevent a change of the unloading order that is inconvenient for the worker W involved in changing the unloading order. Consequently, even when the unloading order is changed, the parts can be more smoothly supplied to the parts mounting device 15.

According to this embodiment, as described above, the external PC 30 is configured or programmed to perform a control to notify the worker W involved in changing the unloading order of the detection result of whether or not the unloading order can be changed when the worker W involved in changing the unloading order is queried in advance regarding whether or not to permit the unloading order to be changed. Accordingly, the worker W involved in changing the unloading order can determine whether or not to permit the unloading order based on the detection result of whether or not the unloading order can be changed.

According to this embodiment, as described above, the external PC 30 is configured or programmed to perform a control to not change the order in which the parts E are unloaded from the parts storage 20 when the worker W who has been queried regarding whether or not to permit the unloading order to be changed responds that the unloading order cannot be permitted to be changed, and to change the order in which the parts E are unloaded from the parts storage 20 when the worker W who has been queried regarding whether or not to permit the unloading order to be changed responds that the unloading order can be permitted to be changed. Accordingly, the unloading order can be changed while the intention of the worker W involved in changing the unloading order is more reliably reflected, and thus it is possible to more reliably significantly reduce or prevent a change of the unloading order that is inconvenient for the worker W involved in changing the unloading order.

According to this embodiment, as described above, the external PC 30 is configured or programmed to perform a control to change the order in which the parts E are unloaded from the parts storage 20 even when the worker W who has been queried regarding whether or not to permit the unloading order to be changed does not respond within the predetermined period of time. Accordingly, when the worker W who has been queried regarding whether or not to permit the unloading order to be changed does not respond, the unloading order can be changed, and thus it is possible to significantly reduce or prevent the possibility that it becomes impossible to change the unloading order due to no response from the worker W who has been queried regarding whether or not to permit the unloading order to be changed.

According to this embodiment, as described above, the external PC 30 is configured or programmed to allow whether or not the worker W involved in changing the unloading order is queried in advance regarding whether or not to permit the unloading order to be changed to be set therein. Accordingly, in the production status that requires a query regarding whether or not to permit the unloading order to be changed, the setting is selected to make a query such that it is possible to significantly reduce or prevent an inconvenient change of the unloading order. In the production status that does not require a query regarding whether or not to permit the unloading order to be changed, the setting is selected not to make a query such that it is possible to save the worker W the trouble of responding to whether or not to permit the unloading order to be changed.

According to this embodiment, as described above, the external PC 30 is configured or programmed to perform a control to query in advance the worker W involved in changing the unloading order regarding whether or not to permit the unloading order to be changed in response to the unloading order change request from the worker W. Accordingly, when the worker W requests the change of the unloading order according to their own convenience, the unloading order can be changed while the intention of the worker W involved in changing the unloading order is reflected. Consequently, it is possible to effectively significantly reduce or prevent a change of the unloading order that is inconvenient for the worker W involved in changing the unloading order.

According to this embodiment, as described above, the external PC 30 is configured or programmed to perform a control to change the order in which the parts E are unloaded from the parts storage 20 such that the turn is advanced or delayed in response to the unloading order change request from the worker W. Accordingly, when the order in which the parts E are unloaded from the parts storage 20 is changed such that the turn is advanced, the parts E that are urgently needed can be quickly unloaded from the parts storage 20, and thus the urgently needed parts E can be quickly supplied to the parts E mounting device. When the order in which the parts E are unloaded from the parts storage 20 is changed such that the turn is delayed, the turn of the parts E that are not urgently needed is delayed according to the convenience of the worker W, such as not being able to collect the parts E, such that other parts E can be unloaded from the parts storage 20.

According to this embodiment, as described above, the parts mounting system 100 includes the mobile terminal 40 that is carried by the worker W to create the unloading order change request. Accordingly, the unloading order change request can be created with the mobile terminal 40, and thus the worker W can make the unloading order change request regardless of the location.

According to this embodiment, as described above, the mobile terminal 40 is configured to display the unloading order list and the unloading priority. Accordingly, the worker W can make the unloading order change request while referring to the unloading order list and the unloading priority, and thus it is possible to easily make an appropriate unloading order change request.

According to this embodiment, as described above, the external PC 30 is configured or programmed to perform a control to notify the mobile terminal 40 carried by the worker W involved in changing the unloading order of the query regarding whether or not to permit the unloading order to be changed. Accordingly, the worker W can receive the notification of the query regarding whether or not to permit the unloading order to be changed through the mobile terminal 40 regardless of the location, and thus the worker W can quickly and reliably confirm the query regarding whether or not to permit the unloading order to be changed.

According to this embodiment, as described above, the parts mounting system 100 includes the plurality of mounting lines 10 including the parts mounting devices 15. Furthermore, the external PC 30 is configured or programmed to perform a control to query in advance the worker W in charge of the mounting line 10 involved in changing the unloading order other than the specific mounting line 10 regarding whether or not to permit the unloading order to be changed in response to the unloading order change request from the worker W in charge of the specific mounting line 10. Accordingly, when the worker W in charge of the specific mounting line 10 requests the change of the unloading order according to the convenience of their mounting line 10, the unloading order can be changed while the intention of the worker W in charge of another mounting line 10 involved in changing the unloading order is reflected. Consequently, it is possible to more effectively significantly reduce or prevent a change of the unloading order that is inconvenient for the worker W involved in changing the unloading order.

According to this embodiment, as described above, the external PC 30 is configured or programmed to perform a control to detect whether or not the order in which the parts E are unloaded from the parts storage 20 is changed based on the unloading priority, and to query in advance the worker W involved in changing the unloading order regarding whether or not to permit the unloading order to be changed when it is detected that the order in which the parts E are unloaded from the parts storage 20 is changed. Accordingly, when the external PC 30 automatically changes the unloading order based on the priority, the unloading order can be changed while the intention of the worker W involved in changing the unloading order is reflected. Consequently, it is possible to effectively significantly reduce or prevent a change of the unloading order that is inconvenient for the worker W involved in changing the unloading order.

According to this embodiment, as described above, the parts mounting system 100 includes the plurality of mounting lines 10 including the parts mounting devices 15. Furthermore, the external PC 30 is configured or programmed to perform a control to query in advance the worker W in charge of the mounting line 10 involved in changing the unloading order among the plurality of mounting lines 10 regarding whether or not to permit the unloading order to be changed when it is detected that the order in which the parts E are unloaded from the parts storage 20 is changed. Accordingly, when the external PC 30 automatically changes the unloading order based on the priority, the unloading order can be changed while the intention of the worker W in charge of the mounting line 10 involved in changing the unloading order is reflected. Consequently, it is possible to more effectively significantly reduce or prevent a change of the unloading order that is inconvenient for the worker W involved in changing the unloading order.

### MODIFIED EXAMPLES

The embodiment disclosed this time must be considered as illustrative in all points and not restrictive. The scope of the present disclosure is not shown by the above description of the embodiment but by the scope of claims for patent, and all modifications (modified examples) within the meaning and scope equivalent to the scope of claims for patent are further included.

For example, while the example in which the external PC functions as a controller that performs a control to query in advance the worker involved in changing the unloading order regarding whether or not to permit the unloading order to be changed when unloading the parts from the parts storage has been shown in the aforementioned embodiment, the present disclosure is not restricted to this. In the present disclosure, the parts storage or the mobile terminal, for example, other than the external PC may function as a controller that performs a control to query in advance the worker involved in changing the unloading order regarding whether or not to permit the unloading order to be changed when unloading the parts from the parts storage.

While the example in which the parts containing member is a reel on which a tape that holds a plurality of parts is wound has been shown in the aforementioned embodiment, the present disclosure is not restricted to this. In the present disclosure, the parts containing member may be a tray on which a plurality of parts are placed. Alternatively, the parts containing members may be a stick including a long case in which parts are stored adjacent to each other in the longitudinal direction of the long case and including an opening on an end face that is orthogonal to the longitudinal direction, through which the parts are supplied one by one.

While the example in which three parts mounting devices are provided on one mounting line has been shown in the aforementioned embodiment, the present disclosure is not restricted to this. In the present disclosure, two or less or four or more parts mounting devices may be provided on one mounting line.

While the example in which one parts storage is provided has been shown in the aforementioned embodiment, the present disclosure is not restricted to this. In the present disclosure, a plurality of parts storages may be provided.

While the example in which in the external PC 30 (controller), whether or not the worker W involved in changing the unloading order is queried in advance regarding whether or not to permit the unloading order to be changed is settable has been shown in the aforementioned embodiment, the present disclosure is not restricted to this. In the present disclosure, the controller may be configured or programmed to perform a control to constantly query in advance the worker W involved in changing the unloading order regarding whether or not to permit the unloading order to be changed.

While the example in which the external PC 30 (controller) is configured or programmed to perform both the manual unloading order change process and the automatic unloading order change process has been shown in the aforementioned embodiment, the present disclosure is not restricted to this. In the present disclosure, the controller may be configured or programmed to perform only one of the manual unloading order change process and the automatic unloading order change process.

While the control process is described, using the flow described in a manner driven by a flow in which processes are performed in order along a process flow for the convenience of illustration in the aforementioned embodiment, the present disclosure is not restricted to this. In the present disclosure, the control process may be performed in an event-driven manner in which processes are performed on an event basis. In this case, the control process may be performed in a complete event-driven manner or in a combination of an event-driven manner and a manner driven by a flow.

What is claimed is:

1. A parts mounting system comprising:
a parts mounting device configured to mount parts on a board;
a parts storage configured to store the parts supplied to the parts mounting device; and
a controller configured or programmed to perform a control to detect whether or not an unloading order can be changed based on whether or not the parts can be supplied to the parts mounting device in time when an order in which the parts are unloaded from the parts storage is changed.

2. The parts mounting system according to claim 1, wherein the controller is configured or programmed to perform a control to query in advance a worker involved in changing the unloading order regarding whether or not to permit the unloading order to be changed.

3. The parts mounting system according to claim 2, wherein the controller is configured or programmed to perform a control to notify the worker involved in changing the unloading order of a detection result of whether or not the unloading order can be changed when the worker involved in changing the unloading order is queried in advance regarding whether or not to permit the unloading order to be changed.

4. The parts mounting system according to claim 2, wherein the controller is configured or programmed to perform a control to refrain from changing the order in which the parts are unloaded from the parts storage when the worker who has been queried regarding whether or not to permit the unloading order to be changed responds that the unloading order cannot be permitted to be changed, and to change the order in which the parts are unloaded from the parts storage when the worker who has been queried regarding whether or not to permit the unloading order to be changed responds that the unloading order can be permitted to be changed.

5. The parts mounting system according to claim 4, wherein the controller is configured or programmed to perform a control to change the order in which the parts are unloaded from the parts storage even when the worker who has been queried regarding whether or not to permit the unloading order to be changed does not respond within a predetermined period of time.

6. The parts mounting system according to claim 2, wherein the controller is configured or programmed to allow whether or not the worker involved in changing the unloading order is queried in advance regarding whether or not to permit the unloading order to be changed to be set therein.

7. The parts mounting system according to claim 2, wherein the controller is configured or programmed to perform a control to query in advance the worker involved in changing the unloading order regarding whether or not to permit the unloading order to be changed in response to an unloading order change request from a worker.

8. The parts mounting system according to claim 7, wherein the controller is configured or programmed to perform a control to change the order in which the parts are unloaded from the parts storage such that a turn is advanced or delayed in response to the unloading order change request from the worker.

9. The parts mounting system according to claim 7, further comprising:
a mobile terminal that is carried by the worker to create the unloading order change request.

10. The parts mounting system according to claim 9, wherein the mobile terminal is configured to display an unloading order list and an unloading priority.

11. The parts mounting system according to claim 9, wherein the controller is configured or programmed to perform a control to notify the mobile terminal carried by the worker involved in changing the unloading order of a query regarding whether or not to permit the unloading order to be changed.

12. The parts mounting system according to claim 2, further comprising:
a plurality of mounting lines including the parts mounting device; wherein
the controller is configured or programmed to perform a control to query in advance the worker in charge of a mounting line involved in changing the unloading order other than a specific mounting line among the plurality of mounting lines regarding whether or not to permit the unloading order to be changed in response to the unloading order change request from a worker in charge of the specific the mounting line.

13. The parts mounting system according to claim 2, wherein the controller is configured or programmed to perform a control to detect whether or not the order in which the parts are unloaded from the parts storage is changed based on an unloading priority, and to query in advance the worker involved in changing the unloading order regarding whether or not to permit the unloading order to be changed when it is detected that the order in which the parts are unloaded from the parts storage is changed.

14. The parts mounting system according to claim 13, further comprising:
a plurality of mounting lines including the parts mounting device; wherein
the controller is configured or programmed to perform a control to query in advance the worker in charge of a mounting line involved in changing the unloading order among the plurality of mounting lines regarding whether or not to permit the unloading order to be changed when it is detected that the order in which the parts are unloaded from the parts storage is changed.

15. A parts mounting method comprising:
mounting parts on a board by a parts mounting device;
unloading the parts supplied to the parts mounting device from a parts storage; and
performing a control to detect whether or not an unloading order can be changed based on whether or not the parts can be supplied to the parts mounting device in time when an order in which the parts are unloaded from the parts storage is changed.

16. The parts mounting system according to claim 3, wherein the controller is configured or programmed to perform a control to refrain from changing the order in which the parts are unloaded from the parts storage when the worker who has been queried regarding whether or not to permit the unloading order to be changed responds that the unloading order cannot be permitted to be changed, and to change the order in which the parts are unloaded from the parts storage when the worker who has been queried regarding whether or not to permit the unloading order to be changed responds that the unloading order can be permitted to be changed.

17. The parts mounting system according to claim 3, wherein the controller is configured or programmed to allow whether or not the worker involved in changing the unloading order is queried in advance regarding whether or not to permit the unloading order to be changed to be set therein.

18. The parts mounting system according to claim 3, wherein the controller is configured or programmed to perform a control to query in advance the worker involved in changing the unloading order regarding whether or not to permit the unloading order to be changed in response to an unloading order change request from a worker.

19. The parts mounting system according to claim 8, further comprising:
a mobile terminal that is carried by the worker to create the unloading order change request.

20. The parts mounting system according to claim 10, wherein the controller is configured or programmed to perform a control to notify the mobile terminal carried by the worker involved in changing the unloading order of a query regarding whether or not to permit the unloading order to be changed.
